(19) United States
(12) Patent Application Publication
(10) Pub. No.: US 2005/0095830 A1
(43) Pub. Date: May 5, 2005

(54) Selective self-initiating electroless capping of copper with cobalt-containing alloys

(75) Inventors: Timothy Weidman, Sunnyvale, CA (US); Zhize Zhu, Cupertino, CA (US)

Correspondence Address: MOSER, PATTERSON & SHERIDAN, LLP/;APPLIED MATERIALS, INC., 3040 POST OAK BOULEVARD, SUTIE 1500, HOUSTON, TX, 77056, US

(73) Assignee: APPLIED MATERIALS, INC.

(21) Appl. No.: 10/967,644

(22) Filed: Oct. 15, 2004

Related U.S. Application Data
(60) Provisional application No. 60/512,334, filed on Oct. 17, 2003.
(60) Provisional application No. 60/512,644, filed on Oct. 20, 2003.

(51) Int. Cl. H01L 21/20

(52) U.S. Cl. 438/584

(57) ABSTRACT

Embodiments of the invention generally provide compositions of plating solutions, methods to mix plating solutions and methods to deposit capping layers with plating solutions. The plating solutions described herein may be used as electroless deposition solutions to deposit capping layers on conductive features. The plating solutions are rather dilute and contain strong reductants to self-initiate on the conductive features. The plating solutions may provide in-situ cleaning processes for the conductive layer while depositing capping layers free of particles. In one embodiment, a method for forming an electroless deposition solution is provided which includes forming a conditioning buffer solution with a first pH value and comprising a first complexing agent, forming a cobalt-containing solution with a second pH value and comprising a cobalt source, a tungsten source and a second complexing agent, forming a buffered reducing solution with a third pH value and comprising a hypophosphite source and a borane reductant, combining the conditioning buffer solution, the cobalt-containing solution and the buffered reducing solution to form the electroless deposition solution. The electroless deposition solution includes the cobalt source in a concentration range from about 1 mM to about 30 mM, the tungsten source in a concentration range from about 0.1 mM to about 5 mM, the hypophosphite source in a concentration range from about 5 mM to about 50 mM, the borane reductant in a concentration range from about 5 mM to about 50 mM, and has a total pH value in a range from about 8 to about 10.

### CROSS-REFERENCE TO RELATED APPLICATIONS

This application claims benefit of U.S. Provisional Patent Application Ser. No. unknown, entitled, “Self-Activating Electroless Deposition Process for Cobalt-Containing Alloys,” filed Oct. 7, 2004, and U.S. Provisional Patent Application Ser. No. 60/512,334, entitled, “Self-Activating Electroless Deposition Process for CoWP Alloys,” filed Oct. 17, 2003, which are both herein incorporated by reference.

### BACKGROUND OF THE INVENTION

1. Field of the Invention

Embodiments of the invention generally relate to compositions, kits and methods for forming and using electroless deposition solutions to deposit capping layers over conductive layers in electronic devices, and more particularly for depositing cobalt-containing layers on copper surfaces.

2. Description of the Related Art

Copper and its alloys have become the metals of choice for sub-micron interconnect technology because copper has a lower resistivity than aluminum, (1.67 μΩ-cm compared to 3.1 μΩ-cm for aluminum at room temperature), a higher current carrying capacity and significantly higher electromigration resistance. These characteristics are important for supporting the higher current densities experienced at high levels of integration and increased device speed. Further, copper has a good thermal conductivity and is available in a highly pure state.

However, despite these attributes, copper diffuses rapidly through silicon, silicon dioxide and most dielectric materials on a substrate and may still form a poor contact at interfaces resulting in weak adhesion to copper. Therefore, a barrier layer must encapsulate the copper layer to prevent diffusion. Also, copper readily forms copper oxide when exposed to atmospheric conditions. Therefore, a copper diffusion layer should also be a barrier to copper oxidation. The formation of copper oxides at the interface between metal layers can increase the resistance of the electrical circuit (e.g., copper interconnects) and reduce the reliability of the overall circuit.

One solution is to selectively deposit a metal alloy on copper surfaces which provides an efficient barrier to copper diffusion, electromigration and oxidation. This appears most readily accomplished using an electroless plating process selective for copper relative to dielectric material. Cobalt-containing alloys, such as cobalt tungsten phosphide (CoWP), are materials established to meet many or all requirements and may be deposited by electroless deposition techniques, though copper generally does not satisfactorily catalyze or initiate deposition of these materials from standard electroless solutions. While deposition of cobalt-containing alloys may be easily initiated electrochemically (e.g., by applying a sufficiently negative potential), a continuous conductive surface over the substrate surface is required and not available following Cu-CMP processes.

An established approach to initiating electroless deposition on copper surfaces is to deposit a thin layer of a catalytic metal on the copper surfaces by displacement plating. However, deposition of the catalytic material may require multiple steps or use of catalytic colloid compounds. Catalytic colloid compounds may adhere to dielectric materials on the substrate surface and result in undesired, non-selective deposition of the capping alloy material. Non-selective deposition of metal alloy capping material may lead to surface contamination and eventual device failure from short circuits and other device irregularities.

The prior art discloses cobalt-containing capping layers are deposited from electroless plating solutions. Generally, the more concentrated the plating solution, the more likely precipitates form. However, plating solutions with high chemical concentrations (e.g., about 0.05 M to 1.0 M) have been traditionally desirable, since the ratio of individual components in the solutions depletes more slowly during the deposition process. Plating solutions containing low chemical concentrations (e.g., <0.05 M) have a tendency to rapidly deplete metals and reducing agents through the deposition/plating process or by oxidation from ambient oxygen.

A copper conductive layer is usually cleaned to remove various contaminants, such as oxides and polymeric residue and then activated by displacement plating, such as with palladium, prior to depositing a capping layer. The substrate is generally cleaned and activated by multiple steps before depositing the capping layer and transferred to another chamber for depositing a capping layer. The cleaned copper surface is susceptible to further oxidation/contamination while being transferred between the cleaning chamber and the deposition chamber, therefore the time the freshly cleaned surfaces are exposed to the atmosphere can be critical when forming a robust semiconductor device.

Therefore, there is a need for a simpler, more robust and less defect prone process for the selective deposition of barrier alloys over conductive layers. There is also a need for a process which combines pre-clean and plating processes without intermediate exposure of the substrate to air.

### SUMMARY OF THE INVENTION

In one embodiment, a method for forming an electroless deposition solution is provided which includes forming a conditioning buffer solution with a first pH value and comprising a first combination of complexing agents (e.g., citrate, glycine and DEA), forming a cobalt-containing solution with a second pH value and comprising a cobalt source, a tungsten source and a second complexing agent, forming a buffered reducing solution with a third pH value and comprising a hypophosphite source and a borane reductant and a third complexing agent. The method further includes combining the conditioning buffer solution, the cobalt-containing solution and the buffered reducing solution to form an active electroless deposition solution. The electroless deposition solution includes a cobalt concentration range from about 1 mM to about 30 mM, a tungsten concentration range from about 0.1 mM to about 5 mM, a hypophosphite concentration range from about 5 mM to about 50 mM, a borane concentration range from about 5 mM to about 50 mM, and has a total pH value in a range from about 8 to about 10.

In another embodiment, a kit for forming an electroless deposition solution is provided which includes a conditioning buffer solution having a first pH value and comprising a first complexing agent, a cobalt-containing solution having a second pH value and comprising a cobalt source, a secondary metal source and a second complexing agent, a buffered reducing solution having a third pH value and comprising a hypophosphite source, a borane reductant and an additional reducing agent. The kit further includes instructions to combine at least the conditioning buffer solution, the cobalt-containing solution and the buffered reducing solution to form the electroless deposition solution.

In another embodiment, a kit for forming a citrate-based deposition solution is provided which includes a conditioning buffer solution having a first pH value and comprising citrate and an alkanolamine, a cobalt-containing solution having a second pH value and comprising a cobalt source, a secondary metal source and citrate, a buffered reducing solution having a third pH value and comprising a hypophosphite source, a borane reductant and citrate. The kit further includes instructions to combine at least the conditioning buffer solution, the cobalt-containing solution and the buffered reducing solution to form the citrate-based deposition solution.

In another embodiment, a method to deposit a cobalt-containing layer on a conductive layer disposed on a substrate surface by an electroless deposition process is provided which includes combining a first volume of a conditioning buffer solution, a second volume of a cobalt-containing solution and a third volume of a buffered reducing solution to form a plating solution, and forming a cobalt-containing layer on the conductive layer by exposing the substrate surface to the plating solution.

In another embodiment, a composition of a plating solution is provided which includes a cobalt source in a concentration range from about 5 mM to about 20 mM, a tungsten source in a concentration range from about 0.2 mM to about 5 mM, a hypophosphite source in a concentration range from about 5 mM to about 50 mM, a borane reductant in a concentration range from about 2 mM to about 50 mM, a citrate in a concentration range from about 90 mM to about 200 mM, an alkanolamine in a concentration range from about 50 mM to about 150 mM, boric acid in a concentration range from about 1 mM to about 20 mM, a surfactant in a concentration range of about 50 ppm or less, and a pH adjusting agent at a concentration to maintain a pH from about 8 to about 10. Optionally, the composition may also contain one or more stabilizers in concentrations of about 100 ppm or less.

In another embodiment, a composition of a plating solution is provided which includes a cobalt source in a concentration range from about 5 mM to about 20 mM, a secondary metal source in a concentration range of about 5 mM or less, a hypophosphite source in a concentration range from about 5 mM to about 50 mM, a borane reductant in a concentration range from about 2 mM to about 50 mM, a citrate in a concentration range from about 90 mM to about 200 mM, an alkanolamine in a concentration range from about 50 mM to about 150 mM, a boric acid in a concentration range from about 1 mM to about 20 mM, a surfactant in a concentration range of about 50 ppm or less, and a pH adjusting agent at a concentration to maintain a pH from about 8 to about 10.

In another embodiment, a method to deposit a cobalt-containing layer by an electroless deposition process is provided which includes exposing a conductive layer on a substrate to an activation solution to form an activated conductive layer, combining a conditioning buffer solution, a cobalt-containing solution and a buffered reducing solution to form a plating solution, and exposing the activated conductive layer to the plating solution to deposit the cobalt-containing layer.

In another embodiment, a method for forming an electroless deposition solution is provided which includes maintaining a conditioning buffer solution at a first temperature, maintaining a metal-containing solution at a second temperature, maintaining a reducing solution at a third temperature, maintaining water at a fourth temperature, and combining the conditioning buffer solution, the metal-containing solution and the reducing solution and the water to form an electroless deposition solution at a fifth temperature.

In another embodiment, a method for forming an electroless deposition solution is provided which includes removing oxygen from water to have an oxygen concentration of about 1 ppm or less, and combining a conditioning buffer solution, a cobalt-containing solution, a buffered reducing solution and the water to form an electroless deposition solution having a second oxygen concentration of about 3 ppm or less.

In another embodiment, a method for forming an electroless deposition solution is provided which includes forming a conditioning buffer solution comprising at least two complexing agents, forming a cobalt-containing solution, forming a buffered reducing solution, and combining the conditioning buffer solution, the cobalt-containing solution and the buffered reducing solution to form an electroless deposition solution.

In another embodiment, a process for forming a citrate-based deposition solution is provided which includes combining water, a conditioning buffer solution, a metal-containing solution and a buffered reducing solution to form a citrate-based deposition solution, wherein the conditioning buffer solution comprises citrate and an alkanolamine, the metal-containing solution comprises a metal source and citrate, and the reducing solution comprises a hypophosphite source and citrate. In one aspect, a citrate concentration of the citrate-based deposition solution is in a range from about 50 mM to about 300 mM and the metal source has a metal concentration from about 8 mM to about 15 mM. The citrate concentration and the metal concentration is at a ratio at about 8:1 or larger, preferably about 10:1 or larger, and more preferably about 12:1 or larger.

In another embodiment, a method to deposit a cobalt-containing layer by an electroless deposition process on a substrate surface containing a conductive layer is provided which includes exposing the substrate surface to a conditioning buffer solution to form a cleaned conductive layer, combining the conditioning buffer solution, a cobalt-containing solution and a reducing solution to form a plating solution, and exposing the cleaned conductive layer to the plating solution to deposit a cobalt-containing layer thereon.

In another embodiment, a method to deposit a cobalt-containing layer by an electroless deposition process on a substrate surface containing a conductive layer is provided which includes exposing the substrate surface to a buffered reducing solution to form a cleaned conductive layer, combining a conditioning buffer solution, a cobalt-containing solution and the buffered reducing solution to form a plating solution, and exposing the cleaned conductive layer to the plating solution to deposit a cobalt-containing layer thereon.

In another embodiment, an apparatus for forming an electroless deposition solution is provided which includes a first vessel containing a conditioning buffer solution comprising a citrate, a second vessel containing a metal-containing solution comprising a metal source and citrate, a third vessel containing a buffered reducing solution comprising a hypophosphite source and citrate, a water source of heated, deionized degassed water, and a fourth vessel in fluid communication with the first, second and third vessels and the water source, wherein the fourth vessel contains the electroless deposition solution. In one aspect, the apparatus includes a heated baffle used to reduce metal concentration of a depleted electroless deposition solution.

In another embodiment, a method for forming an electroless deposition solution is provided which includes forming a conditioning buffer solution comprising a first complexing agent, forming a cobalt-containing solution comprising a cobalt source, a tungsten source and a second complexing agent, forming a buffered reducing solution comprising a hypophosphite source and a borane reductant, combining heated water, the conditioning buffer solution, the cobalt-containing solution and the buffered reducing solution is an in-line mixing system to form an electroless deposition solution, and dispersing the electroless deposition solution on a substrate surface within about 60 minutes or less, preferably 10 minutes or less, and more preferably about 2 minutes or less after forming the electroless deposition solution.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1C illustrate stages of capping an interconnect by an embodiment described herein;

FIG. 2 depicts a dual damascene structure with a cobalt-containing capping layer formed by following another embodiment described herein;

FIG. 3 shows images from a scanning electron microscope of cobalt-containing films grown by various embodiments described herein;

FIG. 4 graphically depicts the current leakage of cobalt-containing capping layer on interconnect lines;

FIG. 5 graphically depicts the resistance increase of cobalt-containing capping layer on interconnect lines; and

FIG. 6 illustrates a schematic diagram of an electroless deposition system used to deposit cobalt-containing films by various embodiments described herein.

### DETAILED DESCRIPTION OF THE PREFERRED EMBODIMENT

The words and phrases used herein should be given their ordinary and customary meaning in the art as understood by one skilled in the art unless otherwise further defined. Electroless deposition is broadly defined herein as the deposition of a conductive material from metal ions in a bath over a catalytically active surface by means of a chemical reduction in the absence of an external electric current, such as by an autocatalytic oxidation of a homogenous reducing agent.

Embodiments of the invention provide compositions and kits of plating solutions, methods to mix plating solutions and methods to deposit capping layers with plating solutions. The plating solutions described herein are generally used as electroless deposition solutions to deposit a capping layer on conductive features. Generally, the conductive features include copper or copper alloys while the capping layers include a cobalt-containing material.

Embodiments of the invention include methods and compositions used for electroless deposition of cobalt-containing materials. The inventors have discovered a cost efficient method of forming and using electroless plating solutions. Particle formation within the plating solution is advantageously avoided, since particles incorporated into the plated film during the electroless process can degrade the. quality of the formed semiconductor features. A low metal concentration (<0.05 M) is achieved while reducing the amount of particles formed within the plating solution. A high chelating agent concentration, especially relative to the low metal concentration also attributes to the lack of particle formation. Concentrates of the plating solution are separately maintained until the plating solution is in-line mixed in small volumes and consumed at the point of use. After each processing step, the depleted plating solution is disposed of and thus each substrate is exposed to a virgin plating solution without particulates. Further, the short time duration between the mixing and using the plating solution is kept minimal, to avoid particulate formation.

Generally, a self initiating chemistry and process has been discovered which enables selective deposition on metal features from a multiple component solutions which are mixed just prior to use. Each component solution is stabilized by a relatively high concentration of one or more chelating agents within each component solution. The component solutions are mixed, preferably in line, with heated degassed, deionized water. The heated water provides rapid heating of the combined component solutions without requiring residence time in a conventional heater. Elimination of the residence time in conventional heaters enables a reactive, self initiating solution to be dispensed on a substrate for deposition. The high concentration of chelating agents is diluted in the combined component solution to achieve a chelating agent to metal ratio which facilitates controlled deposition. The composition of the chemistry, as discussed in detail below, is formulated such that the rate determining factor is the chelating concentration. In conventional processes, the deposition rate is primarily determined by diffusion in the boundary layer.

Prior to initiating the deposition process, the substrate is preferably cleaned either ex situ or in situ using the desired cleaning solution. Following deposition, the substrate can then be cleaned and undergo an anneal process.

Aspects of the invention will be described below first with reference to component chemistries, then to combined component chemistries referred to as the plating solution and then to hardware and processes used to form electroless layers using the compositions.

In a preferred embodiment, a primary complexing agent such as citrate is distributed into each of a conditioning buffer solution, a cobalt-containing solution and a buffered reducing solution, allowing each solution to be provided as concentrates from which the active plating bath is prepared by diluting with degassed hot deionized water. When combining and mixing all components, it is advantageous to avoid a condition in which the total concentration of cobalt ions or reducing agent substantially exceeds those targeted in the final plating solution, unless the absolute concentration of citrate is also substantially higher, as may be most readily accomplished by the distribution between all three components. One aspect of the invention is a process for effectively mixing the components by reducing viscosity differences resulting from segregation of citrate into a single component, such as the cobalt-containing solution.

In one embodiment, a plating solution is formed by mixing together a conditioning buffer solution, a cobalt-containing solution, a buffered reducing solution and water. Preferably, the conditioning buffer solution, a cobalt-containing solution, a buffered reducing solution are each concentrated component solutions that when combined with water, form the desired plating solution. The additional water constitutes over 50% of the plating solution volume, preferably about 60% or more, more preferably about 70%. Preferably, the water is de-ionized, degassed and heated. In one function, water dilutes each component solution to the desired concentration within the plating solution. Degassing the water removes much of the oxygen and other trapped gas(es). Water is easier to deoxygenate than the mixed plating solution and since water is the major component of the plating solution, the overall oxygen concentration of the plating solution is reduced. Also, heated water transfers thermal energy to the plating solution while combining each of the component solutions. Therefore, the water is heated to a temperature sufficient to elevate the temperature of the components and resulting solution to a desired temperature. Preferably, the final plating solution is about 5° C. to about 10° C. below the substrate temperature during the deposition process.

The conditioning solution is a buffered solution containing chelators/complexing agents, pH buffering compounds and a pH adjusting compound. Also, the conditioning solution contains compounds to aid in the cleaning of the substrate surface and the chelation of copper ions. The cobalt-containing solution is an aqueous solution containing a cobalt source, a secondary metal source, such as a tungsten source or a molybdenum source, chelators/complexing agents, an optional surfactant and a pH adjusting compound. The buffered reducing solution comprises chelators/complexing agents, a reductant or mixture of reductants, an optional stabilizer and a pH adjusting compound. A reductant chemically reduces (i.e., transfers electrons to) the metal ions within the plating solution to form the deposited metal. Preferably, the reductant is a hypophosphite salt derived from, for example, the neutralization of hypophosphorous acid with tetramethylamonium hydroxide (TMAH). The hypophosphorous acid serves as a source of phosphorus in the growing alloy layer. A second reducing agent, which may also be considered as an activator, typically contains reactive boron-hydrogen bonds. One example of a second reducing agent is a dimethylamine borane complex. This co-reductant is highly reactive and is important since it can initiate the reduction of metal ions on the surface of an exposed copper conductor without the need for a metal activation or seed layer. The boron-hydrogen containing activator acts as a co-reductant with the hypophosphite source during the deposition of the cobalt-containing material.

Pre-Clean

A pre-clean process is preformed on the substrate surface prior to depositing a cobalt-containing material. A cleaning solution is dispensed across or sprayed on the substrate surface to clean and precondition the surface. The cleaning process may be an in situ process performed in the same processing cell as the subsequent electroless deposition process. Alternatively, the substrate may be pre-cleaned in a separate processing cell than the subsequent electroless deposition process.

In one embodiment of an in situ pre-clean process, the substrate surface is initially exposed to the conditioning buffer solution prior to being exposed to the complete plating solution. The conditioning buffer solution combined with de-ionized water is dispensed across or sprayed on the substrate surface to clean and precondition the surface prior to deposition of the cobalt-alloy layer. The conditioning buffer solution removes copper oxides and contaminants. In another example, the substrate surface is first exposed to a mixture of a conditioning buffer solution, a cobalt-containing solution and de-ionized water. The exposure to a pre-clean solution formed from a component solution is preferably conducted in the same cell as the subsequent deposition process. Therefore, the cleaned substrate surface is never exposed to the ambient atmosphere (e.g., O₂) between a cleaning process and a plating process. Following the cleaning process, the cleaned substrate is exposed to a plating solution comprised of a conditioning buffer solution, a cobalt-containing solution, a buffered reducing solution and de-ionized water.

In another embodiment, the substrate surface is pre-cleaned with a pre-clean solution other than a component solution of the plating solution. The pre-clean process may be conducted in the same cell or in a different cell from the electroless deposition chamber. The pre-clean process usually includes an acidic pre-clean solution with a pH of about 4 or less, preferably, from about 1.5 to about 3. The more heavily oxidized surfaces typically required more aggressive cleaning at lower pH values. The pre-clean solution contains at least one chelator or complexing agent, such as a carboxylic acid or carboxylate, for example, a citrate, oxalic acid, glycine, salts thereof and combinations thereof. In one example, the pre-clean contains about 0.05 M to about 0.5 M of citric acid and optionally up to about 0.25 M of methanesulfonic acid.

Conditioning Buffer Concentrate

The conditioning buffer solution is a concentrate that contains chelators or complexing agents, buffers, pH adjusting compounds and water. Chelators or complexing agents are usually in the conditioning buffer solution with a concentration from about 200 mM to about 2 M, preferably from about 200 mM to about 600 mM. Complexing agents generally may have functional groups, such as amino acids, carboxylic acids, dicarboxylic acids, polycarboxylic acids, amino acids, amines, diamines, polyamines, alkylamines, alkanolamines and alkoxyamines. Complexing agents may include citric acid, glycine, ethylenediamine (EDA), monoethanolamine, diethanolamine (DEA), triethanolamine (TEA), derivatives thereof, salts thereof and combinations thereof. In one embodiment, citric acid or the respective citrate salt is a preferred complexing agent. In another embodiment, citric acid and glycine are both included in the conditioning buffer solution. In another embodiment, citric acid, DEA and glycine are included in the conditioning buffer solution.

Conditioning buffer solutions generally contain basified acids at basic pH ranges to form the respective salt of the acid. For example, citric acid is converted to a citrate salt, such as ammonium citrate or tetramethyl ammonia citrate. Citrate salts buffer the solution as well as chelate or complex metal ions in the subsequent plating solution. Alkanolamines, such as DEA or TEA, function as a pH adjusting agent, a buffering agent, a chelator/complexing agent and an anti-drying agent. As an anti-drying agent, alkanolamines keep puddles of plating solution from drying and forming precipitates. Alkanolamines are also believed to improve the wetting characteristics of the plating bath with respect to less polar, carbon containing dielectric materials. Glycine is added to increase buffering capacity at the desired pH and to insure more complete removal of both cupric and cuprous oxides form the copper surface. Boric acid may be added to provide additional buffering and to stabilize the composition of the solution. Boric acid is an oxidation by-product from subsequent reduction reactions of plating solutions utilizing borane reductants. Therefore, the addition of boric acid in the conditioning buffer solution helps normalize the reactivity of the fresh composition with one in which plating has already been initiated.

In one embodiment, a pH adjusting agent is added to the conditioning buffer solution to adjust the pH range from about 8 to about 12, preferably from about 8 to about 10 and more preferably from about 8.5 to about 9.5. Once the conditioning buffer solution is combined with about 7 volumetric equivalents of deionized water, the pH is about 9.5. The pH adjusting agent can include ammonia, amines or hydroxides, such as tetramethylammonium hydroxide ((CH₃)₄NOH, TMAH), NH₄OH, TEA, DEA, salts thereof, derivatives thereof and combinations thereof.

In one example, a conditioning buffer solution contains a DEA concentration from about 300 mM to about 600 mM, preferably about 450 mM, a citric acid concentration from about 200 mM to about 500 mM, preferably about 375 mM, a glycine concentration from about 100 mM to about 300 mM, preferably about 150 mM, a boric acid concentration from about 10 mM to about 100 mM, preferably about 50 mM, deionized water and enough pH adjusting agent (e.g., TMAH) to have a pH from about 8 to about 10, preferably, from about 9 to about 9.5, and more preferably, about 9.25.

In another example, a conditioning buffer solution contains a DEA concentration from about 800 mM to about 1.2 M, preferably about 1 M, a citric acid concentration from about 300 mM to about 400 mM, preferably about 375 mM, a glycine concentration from about 200 mM to about 600 mM, preferably about 300 mM, a boric acid concentration from about 80 mM to about 120 mM, preferably about 100 mM, deionized water and enough pH adjusting agent (e.g., TMAH) to have a pH from about 8 to about 10, preferably, from about 9 to about 9.5 and more preferably, about 9.25.

Cobalt-Containing Concentrate

Generally, the cobalt-containing solution is a concentrate that includes a cobalt source, a second metal source, such as a tungsten source or a molybdenum source, a complexing agent or chelator, a pH adjusting agent, an optional surfactant, other optional additives and water. The cobalt-containing solution contains a cobalt source that may be in a concentration range from about 50 mM to about 200 mM, preferably from about 80 mM to about 150 mM. The cobalt source may include any water soluble cobalt source (e.g., Co²⁺), for example cobalt sulfate (COSO₄), cobalt chloride (COCl₂), cobalt acetate ((CH₃CO₂)₂Co), cobalt tungstate (CoWO₄), derivatives thereof, hydrates thereof and combinations thereof. Some cobalt sources have hydrate derivatives, such as CoSO₄.7H₂O, CoCl₂.6H₂O and (CH₃CO₂)₂Co.4H₂O. In one example, cobalt sulfate is the preferred cobalt source. For example, CoSO₄.7H₂O may be present in the cobalt-containing solution at a concentration in a range from about 50 mM to about 150 mM. In another example, CoCl₂.6H₂O may be present in the cobalt-containing solution at a concentration in a range from about 50 mM to about 150 mM.

The cobalt-containing solution includes a secondary metal source, such as a tungsten source or a molybdenum source. A tungsten source may be in the cobalt-containing solution with a concentration in a range from about 0.5 mM to about 50 mM, preferably from about 1 mM to about 30 mM, and more preferably from about 10 mM to about 30 mM. The tungsten source may include tungstic acid (H₂WO₄) and various tungstate salts, such as ammonium tungsten oxide or ammonium tungstate, cobalt tungstate (CoWO₄), sodium tungstate (Na₂WO₄), potassium tungstate (K₂WO₄), other water soluble WO₄²⁻ sources, hydrates thereof, derivatives thereof and/or combinations thereof. In one example, tungstic acid is the preferred tungsten source and may be present in the cobalt-containing solution at a concentration in a range from about 10 mM to about 30 mM.

A molybdenum source may be in the cobalt-containing solution with a concentration range from about 20 ppm to about 1,000 ppm, preferably, from about 50 ppm to about 500 ppm, and more preferably, from about 100 ppm to about 300 ppm. The molybdenum source may include molybdenum trioxide (MoO₃) and various molybdate salts, such as tetramethylammonium molybdate ((Me₄N)₂MoO₄), ammonium dimolybdate, sodium molybdate (Na₂MoO₄), potassium molybdate (K₂MoO₄), other MoO₄²⁻ sources, hydrates thereof, derivatives thereof and/or combinations thereof. In one example, molybdenum trioxide is the preferred molybdenum source and may be present in the cobalt-containing solution at a concentration in a range from about 100 ppm to about 300 ppm. In another example, tetramethylammonium molybdate is formed by reacting molybdenum (VI) oxide with tetramethylammonium hydroxide and may be present in the cobalt-containing solution at a concentration in a range from about 100 ppm to about 300 ppm.

A complexing agent is also present in the cobalt-containing solution that may have a concentration in a range from about 100 mM to about 750 mM, preferably from about 200 mM to about 500 mM. In the cobalt-containing solution, complexing agents or chelators form complexes with cobalt ions (e.g., Co²⁺). Complexing agents may also provide buffering characteristics in the cobalt-containing solution. Complexing agents generally may have functional groups, such as amino acids, carboxylic acids, dicarboxylic acids, polycarboxylic acids, and amines, diamines and polyamines. Complexing agents may include carboxylic acids, amino acids, amines, such as citric acid, glycine, ethylene diamine (EDA), derivatives thereof, salts thereof and combinations thereof. In one embodiment, citric acid is the preferred complexing agent. For example, citric acid may be present in the cobalt-containing solution at a concentration in a range from about 200 mM to about 500 mM. In another example, glycine may be present in a concentration in a range from about 100 mM to about 300 mM.

A pH adjusting agent, generally a base, is used to adjust the pH of the cobalt-containing solution. In one embodiment, a pH adjusting agent is added to a concentration to adjust the pH to a range from about 7 to about 11, preferably from about 8 to about 10, and more preferably, from about 8.5 to about 9.5. The pH adjusting agent may include a base, such as a tetraalkylammonium hydroxide, preferably tetramethylammonium hydroxide ((CH₃)₄NOH, TMAH) or derivatives thereof.

Also, an optional surfactant may be added to the cobalt-containing solution. The surfactant acts as a wetting agent to reduce the surface tension between the plating solution and the substrate surface. Surfactants are generally added to the cobalt-containing solution at a concentration of about 1,000 ppm or less, preferably about 500 ppm or less, such as from about 100 ppm to about 300 ppm. The surfactant may have ionic or non-ionic characteristics. A preferred surfactant includes dodecyl sulfates, such as sodium dodecyl sulfate (SDS). Other surfactants that may be used in the cobalt-containing solution include glycol ether based surfactants (e.g., polyethylene glycol). For example, a glycol ether based surfactants may contain polyoxyethylene units, such as TRITON® 100, available from Dow Chemical Company. Other useful surfactants may contain phosphate units, for example, sodium poly(oxyethylene) phenyl ether phosphate, such as RHODAFAC® RE-610, available from Rhodia, Inc. The surfactants may be single compounds or a mixture of compounds of molecules containing varying length of hydrocarbon chains.

In one example, a cobalt-containing solution includes CoCl₂.6H₂O at a concentration from about 80 mM to about 120 mM, preferably, about 100 mM, H₂WO₄ at a concentration from about 10 mM to about 30 mM, preferably, about 20 mM, citric acid at a concentration from about 300 mM to about 400 mM, preferably, about 375 mM, SDS at a concentration from about 100 ppm to about 300 ppm, preferably, about 200 ppm, deionized water and enough pH adjusting agent (e.g., TMAH) to have a pH from about 8 to about 10, preferably, from about 9 to about 9.5, and more preferably about 9.25.

In another example, a cobalt-containing solution includes CoCl₂.6H₂O at a concentration from about 80 mM to about 120 mM, preferably, about 100 mM, MoO₃ at a concentration from about 50 ppm to about 500 ppm, preferably, about 200 ppm, citric acid at a concentration from about 300 mM to about 400 mM, preferably, about 375 mM, SDS at a concentration from about 100 ppm to about 300 ppm, preferably, about 200 ppm, deionized water and enough pH adjusting agent (e.g., TMAH) to have a pH from about 8 to about 10, preferably, from about 9 to about 9.5, and more preferably about 9.25.

Buffered Reducing Concentrate

A buffered reducing solution is a concentrate that contains a hypophosphite source, an activator or co-reductant, such as a borane reductant, a complexing agent/chelator, a pH adjusting agent, an optional stabilizer and water. A hypophosphite source may be in the buffered reducing solution at a concentration range from about 50 mM to about 500 mM, preferably from about 100 mM to about 300 mM. The hypophosphite source acts as a reductant during the plating process and chemically reduces dissolved metal ions in the plating solution. The hypophosphite source may also be a phosphorus source for the deposited cobalt-containing material (e.g., CoP, CoWP or COWPB). Hypophosphite sources may be selected from hypophosphorous acid (H₃PO₂), salts thereof and combinations thereof. Once dissociated in solution, a hypophosphite source exits as H₂PO₂¹⁻, with salts including Na¹⁺, K¹⁺, Ca²⁺, NH₄¹⁺, (CH₃)₄N¹⁺ (TMA) and combinations thereof, preferably, the hypophosphite source is monobasic tetramethylammonium hypophosphite ([(CH₃)₄N][H₂PO₂]). In one example, a buffered reducing solution is prepared from H₃PO₂ (50 vol %) to give a hypophosphite concentration from about 200 mM to about 300 mM.

The buffered reducing solution also contains an activator or co-reductant, such as a borane reductant, at a concentration from about 50 mM to about 500 mM, preferably from about 100 mM to about 300 mM. Borane reductants serve as reducing agents and potentially as sources of boron in the deposited alloy. In some examples, the inventors have found that boron is not typically incorporated in the cobalt-containing material when the plating solution contains a hypophosphite source. As a reducing agent, the borane reductant chemically reduces (i.e., transfers electrons to) dissolved ions in the plating solution to initiate the electroless plating process. The reduction process deposits the various elements and/or compounds to form the composition of the cobalt-containing alloys, such as cobalt, tungsten or molybdenum, phosphorus, among other elements.

Borane reductants may be borane complexed with at least one donor ligand, such as amines, phosphines, solvents and other compounds that have Lewis base characteristics. Once dissolved in a solution, borane complexes may dissociate or exchange ligands in the plating solution. Borane reductants and boron-sources useful for embodiments of the invention include dimethylamine borane complex ((CH₃)₂NH.BH₃), DMAB), trimethylamine borane complex ((CH₃)₃N.BH₃), TMAB), tert-butylamine borane complex (^{t}BuNH₂.BH₃), tetrahydrofuran borane complex (THF.BH₃), pyridine borane complex (C₅H₅N.BH₃), ammonia borane complex (NH₃.BH₃), borane (BH₃), diborane (B₂H₆), derivatives thereof, complexes thereof and combinations thereof.

In one embodiment, borane reductants may be added to solutions directly or first mixed with solvents, such as water or organic solvents, such as a glycol ether solvent. Glycol ether solvents include methyl, ethyl, propyl and butyl derivatives of the glycol ether family, such as propylene glycol methyl ether, available as Dowanol PMTM, from Dow Chemical Company, herein referred to as PM solvent.

A complexing agent may be present in the buffered reducing solution in a concentration range from about 100 mM to about 750 mM, preferably, from about 200 mM to about 500 mM. In the subsequent plating solution, complexing agents and/or chelators form complexes with cobalt ions (e.g., Co²⁺). Complexing agents also provide buffering characteristics in the buffered reducing solution. Complexing agents include amino acids, carboxylic acids, dicarboxylic acids, polycarboxylic acids, amines, diamines and polyamines. Specific complexing agents used in the buffered reducing solution include citric acid, glycine, ethylenediamine (EDA), derivatives thereof, salts thereof and combinations thereof. In one embodiment, citric acid or citrate is the preferred complexing agent. For example, the cobalt-containing solution may have a citrate concentration in a range from about 200 mM to about 600 mM.

An optional stabilizer may also be added to the buffered reducing solution. The stabilizer selectively complexes with the copper ions (e.g., Cu¹⁺ or Cu²⁺) so that they may be extracted from the substrate surface prior to initiation of plating, and does reduces the tendency to form particles in the solution. Once complexed, the copper ions are easily extracted from the substrate surface prior to initiation of plating. The removal of the copper ions reduces the tendency to nucleate growth of a particle in solution. A useful stabilizer will be water soluble and have a high affinity for complexing copper ions. In the buffered reducing solution, a stabilizer will in general have a concentration from about 20 ppm to about 250 ppm, preferably, from about 80 ppm to about 120 ppm. A preferred stabilizer is hydroxypyridine or derivatives thereof at a concentration of about 80 ppm to about 120 ppm.

A pH adjusting agent is added to adjust the buffered reducing solution to a pH in a range from about 7 to about 12, preferably from about 8 to about 10 and more preferably from about 8.5 to about 9.5. The pH adjusting agent may include a base, such as a tetraalkylammonium hydroxide, preferably tetramethylammonium hydroxide ((CH₃)₄NOH, TMAH) or derivatives thereof. The pH adjusting agent used in the buffered reducing solution may be the same as or different from the pH adjusting agent used in the conditioning buffer solution and/or the cobalt-containing solution.

In one example, a buffered reducing solution includes H₃PO₂ (50%) at a concentration from about 100 mM to about 350 mM, preferably, about 250 mM, DMAB at a concentration from about 100 mM to about 300 mM, preferably, about 200 mM, citric acid at a concentration from about 300 mM to about 400 mM, preferably, about 375 mM, hydroxylpyridine at a concentration from about 25 ppm to about 300 ppm, preferably, about 100 ppm, deionized water and enough pH adjusting agent (e.g., TMAH) to provide a pH from about 8 to about 10, preferably, from about 9 to about 9.5, and more preferably about 9.25.

Plating Solution

A plating solution may be formed by combining a conditioning buffer solution, a cobalt-containing solution and a buffered reducing solution into de-ionized water. Compositions of the plating solution include buffering agents that reduce pH fluctuation and help maintain the dissolved chemical components within the solution. Point-of-use mixing by combining components of a plating solution with in-line mixing is an efficient and effective process.

In one example, the plating solution includes a volumetric equivalent of a conditioning buffer solution, a cobalt-containing solution, a buffered reducing solution and seven volumetric equivalents of deionized water. That is, the volumetric ratio of the conditioning buffer solution, the cobalt-containing solution, the buffered reducing solution and the deionized water is 1:1:1:7. In another example, the plating solution includes a volumetric ratio of the conditioning buffer solution, the cobalt-containing solution, the buffered reducing solution and the water is 2:1:1:6.

The water used to form the plating solution is preferably degassed, deionized water. The water is degassed to decrease the dissolved oxygen concentration. The water preferably has an oxygen concentration less than about 3 ppm, preferably about 1 ppm or less. In a preferred embodiment, the water is heated to a temperature higher than the anticipated temperature of the final plating solution. For example, if the desired temperature of the plating solution is to be about 60° C. to about 70° C., then the water temperature is maintained from about 70° C. to about 95° C., preferably from about 80° C. to about 90° C. Therefore, in one example of forming a plating solution, the volumetric ratio of each component solution is 1:1:1:7 for a conditioning buffer solution at room temperature (about 20° C.), a cobalt-containing solution at room temperature (about 20° C.), a buffered reducing solution at room temperature (about 20° C.) and water at a temperature from about 80° C. to about 90° C. In another example, the plating solution is formed by combining a conditioning buffer solution at about 30° C. or less, a cobalt-containing solution at about 30° C. or less, a buffered reducing solution at about 30° C. or less and water at a temperature from about 80° C. to about 90° C.

The order of combining the component solutions to form the plating bath may vary. Preferably, the conditioning buffer solution, the cobalt-containing solution, the buffered reducing solution and water are blended by in-line mixing just prior to depositing the plating solution on the substrate surface. In the preferred embodiment, the conditioning buffer solution is first added to the water, and then sequentially, the cobalt-containing solution and the buffered reducing solution are added to form the plating solution. In another embodiment, a conditioning buffer solution and a cobalt-containing solution are added to water, and then a buffered reducing solution is added to form the plating solution. In an alternative embodiment, a conditioning buffer solution and a buffered reducing solution are added to water, and then a cobalt-containing solution is added to form the plating solution.

The plating solution is maintained under an inert atmosphere, such as nitrogen or argon. The plating solution is usually formed less than an hour before being used to deposit the cobalt-containing layer. Preferably, the plating solution is mixed about 10 minutes or less, such as 2 minutes or less prior to performing the deposition process. The substrate is exposed to the plating solution having a temperature of about 80° C. to about 85° C. for about 1 minute to about 2 minutes. Generally, about 100 mL to about 300 mL of plating solution is used to deposit a cobalt-containing layer with a thickness of about 200 Å or less, preferably about 100 Å or less.

In one embodiment, the plating solution has a high concentration ratio of citrate to metal ions, such as cobalt and tungsten. The citrate concentration to cobalt and tungsten concentration is at least about 8:1, preferably about 10:1 or about 12:1. Within the plating solutions, it is believed that the citrate concentration controls the rate of deposition more so than the metal concentration. As the deposition process progresses, the wafer is heated and water is evaporated from in the plating solution. In turn, the plating solution becomes more concentrated. However, the increase in citrate concentration due to the evaporation of the water from the plating solution slows the deposition reaction and the reaction normalizes.

Particle formation within the plating solution is advantageously avoided during plating process following embodiments of the invention. The low metal concentration reduces the amount of particles formed within the plating solution. The high chelating agent concentration, especially relative to the low metal concentration also attributes to the lack of particle formation. Further, the short time duration between the mixing and using the plating solution is kept minimal. Also, the plating solution is in-line mixed in small volumes and consumed at point of use. Therefore, the depleted plating solution is disposed of after each use and the substrate is exposed to virgin plating solution without particulates.

In one example, a composition of a plating solution after combining the conditioning buffer solution, the cobalt-containing solution, the buffered reducing solution and water includes a tungsten source in a concentration range from about 0.1 mM to about 5 mM, preferably from about 1 mM to about 3 mM, and more preferably, about 2 mM; a cobalt source in a concentration range from about 1 mM to about 30 mM, preferably from about 5 mM to about 15 mM, and more preferably, about 10 mM; a citrate compound in a concentration range from about 50 mM to about 300 mM, preferably from about 90 mM to about 200 mM, and more preferably, about 150 mM; optional boric acid in a concentration range from about 1 mM to about 50 mM, preferably from about 5 mM to about 20 mM, and more preferably, about 10 mM; a hypophosphite source in a concentration range from about 5 mM to about 50 mM, preferably from about 15 mM to about 35 mM, and more preferably, about 25 mM; a borane reductant with a concentration range from about 5 mM to about 50 mM, preferably from about 10 mM to about 30 mM, and more preferably, about 20 mM; an alkanolamine with a concentration range from about 50 mM to about 200 mM, preferably from about 80 mM to about 120 mM, and more preferably, about 90 mM; glycine with a concentration range from about 10 mM to about 80 mM, preferably from about 20 mM to about 60 mM, and more preferably, about 30 mM; an optional surfactant with a concentration less than 100 ppm, preferably less than 50 ppm, and more preferably, about 20 ppm; an optional stabilizer with a concentration less than 100 ppm, preferably less than 20 ppm, and more preferably, about 10 ppm; and at least one base in a concentration to have the solution with a pH in a range from about 7 to about 12, preferably from about 8 to about 10, and more preferably, from about 8.5 to about 9.5, for example, about 9.25.

In another example, a composition of a plating solution after combining the conditioning buffer solution, the cobalt-containing solution, the buffered reducing solution and water includes a tungsten source in a concentration range from about 0.1 mM to about 5 mM, preferably from about 1 mM to about 3 mM, and more preferably, about 2 mM; a cobalt source in a concentration range from about 1 mM to about 30 mM, preferably from about 5 mM to about 15 mM, and more preferably, about 10 mM; a citrate compound in a concentration range from about 50 mM to about 300 mM, preferably from about 90 mM to about 200 mM, and more preferably, about 113 mM; optional boric acid in a concentration range from about 1 mM to about 50 mM, preferably from about 5 mM to about 20 mM, and more preferably, about 10 mM; a hypophosphite source in a concentration range from about 5 mM to about 50 mM, preferably from about 15 mM to about 35 mM, and more preferably, about 25 mM; a borane reductant with a concentration range from about 5 mM to about 50 mM, preferably from about 10 mM to about 30 mM, and more preferably, about 20 mM; an alkanolamine with a concentration range from about 50 mM to about 200 mM, preferably from about 80 mM to about 120 mM, and more preferably, about 100 mM; glycine with a concentration range from about 10 mM to about 80 mM, preferably from about 20 mM to about 60 mM, and more preferably, about 30 mM; an optional surfactant with a concentration less than 100 ppm, preferably less than 50 ppm, and more preferably, about 20 ppm; an optional stabilizer with a concentration less than 100 ppm, preferably less than 20 ppm, and more preferably, about 10 ppm; and at least one base in a concentration to have the solution with a pH in a range from about 7 to about 12, preferably from about 8 to about 10, and more preferably, from about 8.5 to about 9.5, for example, about 9.25.

In another example, a composition of a plating solution after combining the conditioning buffer solution, the cobalt-containing solution, the buffered reducing solution and water includes a cobalt source at a concentration from about 5 mM to about 15 mM, a secondary metal source at a concentration of about 5 mM or less (e.g., tungsten at about 2 mM or molybdenum at about 200 ppm), a hypophosphite source at a concentration from about 15 mM to about 35 mM, a borane reductant at a concentration from about 10 mM to about 30 mM, a citrate at a concentration from about 90 mM to about 200 mM, an alkanolamine at a concentration from about 50 mM to about 200 mM, a boric acid at a concentration from about 5 mM to about 20 mM, a surfactant at a concentration of about 100 ppm or less, and a pH adjusting agent at a concentration to maintain a pH from about 8 to about 10, preferably, from about 8.5 to about 9.5.

The plating solution may be used to perform an electroless deposition process using puddle plating (e.g., face up) or an immersion style (e.g., face down) process. A face up, puddle type plating process is preferred. Each component solution may be stored in separate bottles or containers to insure a longer shelf life than if combined and stored. Therefore, a plating solution kit may be used to form a plating solution and to deposit a cobalt-containing layer. The plating kit includes a conditioning buffer solution, a cobalt-containing solution, a buffered reducing solution and directions to describe the process of combining and mixing the component solutions with water, such as heated, degassed and de-ionized water.

In one embodiment, each of the component solutions, i.e., the conditioning buffer solution, the cobalt-containing solution and the buffered reducing solution have similar features, such as the pH and the chelator/complexing agent. In a preferred embodiment, each of the component solutions may have the same pH, or substantially the same pH, such as in the range from about 8.5 to about 9.5, preferably, about 9.25. Also, each of the component solutions may have the same chelator/complexing agent, such as a citrate derived from citric acid.

In one embodiment, citrate is a preferred chelator to be present in each component solution or concentrate, such as the conditioning buffer solution, the cobalt-containing solution and the buffered reducing solution. Citrate plays an important role of buffering each of the individual component solution while being combined to form the plating solution. Citrates generally have poor solubility in water at high concentrations. Also, the component solutions are relatively concentrated solutions. Since the desired citrate concentration of the final plating solution is substantial, a single component solution is not capable of completely containing all the dissolved citrate. Therefore, the citrate may be dissolved in each component solution to assure no formation of citrate precipitate.

Plating solutions may be degassed to minimize dissolved oxygen (O₂). Degassing processes include treating any of the solutions during various stages to reduce the oxygen concentration. Some of the degassing processes include membrane contactor systems, sonication, heating, bubbling inert gas (e.g., N₂ or Ar) through the solutions, addition of oxygen scavengers and/or combinations thereof. Membrane contactor systems are usually exclusively used to reduce oxygen concentration in water. Membrane contactor systems include microporous, hollow fibers that are hydrophobic and are generally made from polymers, such as polypropylene. The fibers are selective to gas diffusion while not permitting liquids to pass. Oxygen may be removed from any of the solutions (e.g., water, plating, conditioning buffer, cobalt-containing or buffered reducing) so that the solutions have an oxygen concentration less than about 3 ppm, preferably about 1 ppm or less. Examples of oxygen scavengers useful in the invention include ascorbic acid, N,N-diethylhydroxylamine, erythorbic acid, methyl ethyl ketoxime, carbohydrazide and/or combinations thereof. The concentration of the oxygen scavenger within the plating solution may be as low as about 10 ppm, but usually from about 0.01 mM to about 10 mM, preferably, from about 0.1 mM to about 5 mM. In one embodiment, ascorbic acid is used as an oxygen scavenger in the cobalt-containing solution with the concentration from about 30 mg/L to about 300 mg/L, preferably, about 100 mg/L. Oxygen scavengers may be added to any or all of the solutions, but preferably to the buffered cleaning solution. Alternatively, each of the component solutions, such as the conditioning buffer solution, the cobalt-containing solution and the buffered reducing solution, may be degassed, pre-packaged and sealed under vacuum or inert atmosphere (e.g., N₂ or Ar).

The processes described herein may be performed in an apparatus suitable for performing an electroless deposition process (EDP). A suitable apparatus includes the SLIMCELL™ processing platform that is available from Applied Materials, Inc., located in Santa Clara, Calif. The SLIMCELL™ platform, for example, includes an integrated processing chamber capable of depositing a conductive material by an electroless process, such as an EDP cell, which is available from Applied Materials, Inc., located in Santa Clara, Calif. The SLIMCELL™ platform generally includes one or more EDP cells as well as one or more pre-deposition or post-deposition cell, such as spin-rinse-dry (SRD) cells or annealing chambers. A further description of EDP platforms and EDP cells may be found in the commonly assigned U.S. Provisional Patent Application Ser. No. 60/511,236, entitled, “Apparatus for Electroless Deposition,” filed on Oct. 15, 2003, U.S. Provisional Patent Application Ser. No. 60/539,491, entitled, “Apparatus for Electroless Deposition of Metals on Semiconductor Wafers,” filed on Jan. 26, 2004, U.S. Provisional Patent Application Ser. No. 60/575,553, entitled, “Face Up Electroless Plating Cell,” filed on May 28, 2004, and U.S. Provisional Patent Application Ser. No. 60/575,558, entitled, “Face Down Electroless Plating Cell,” filed on May 28, 2004, which are each incorporated by reference to the extent not inconsistent with the claimed aspects and description herein. The mixing process used to combine the solutions with the various ratios include tank mixing, in-line mixing and/or combinations thereof, preferably in-line mixing

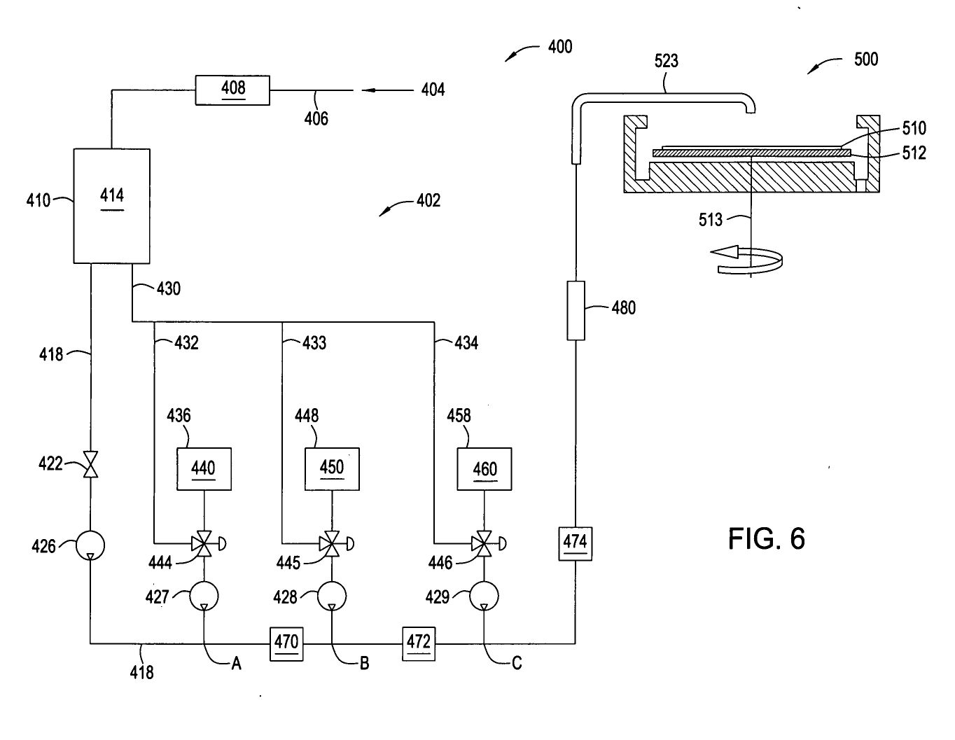

FIG. 6 generally illustrates a schematic view of an exemplary electroless plating system 400. The electroless plating system 400 includes an electroless fluid plumbing system 402 configured to provide a flow of an electroless plating solution comprised of degassed, preheated de-ionized water and a series of electroless processing concentrates to a face-up type processing cell 500 containing a substrate 510. The componential concentrates of the electroless plating solution include conditioning buffer concentrate 440, cobalt-containing concentrate 450 and buffered reducing concentrate 460. A substrate support 512 is disposed in a generally central location in processing cell 500 and has a rotating means 513. A fluid input, such as a nozzle 523, may be disposed in processing cell 500 to deliver electroless plating solutions, in situ cleaning solutions or de-ionized water to the surface of the substrate 510. The nozzle 523 may be disposed over the center of the substrate 510 to deliver a fluid to the center of the substrate 510 or may be disposed in any position. Insulated conduits 430, 432, 433 and 434 may be used in concert with three way valves 444, 445 and 446 to purge remaining conduits during a cleaning process of system 402. A more detailed description of the electroless plating system and electroless fluid plumbing system is described in commonly assigned U.S. Provisional Patent Application No. 60/539,543, entitled, “Method and Apparatus for Selectively Changing Thin Film Composition During Electroless Deposition in a Single Chamber,” filed Jan., 26, 2004, which is incorporated by reference to the extent not inconsistent with the claimed aspects and description herein.

During operation, degassed, preheated de-ionized water 414 is prepared by flowing de-ionized water 404 through an in-line degasser 408 to a water container 410 having a heating source. Passing the de-ionized water 404 through the degasser 408 reduces the amount of dissolved oxygen (O₂) normally present in the de-ionized water 404. The degasser 408 is preferably a contact membrane degasser, although other degassing processes including sonication, heating, bubbling inert gas (e.g., N₂ or Ar), adding oxygen scavengers and combinations thereof, may be used. The water container 410 having a heating source heats the de-ionized water 414 to a temperature in the range of about 80° C. to about 95° C. The heating source may be a microwave heating source external to the water container 410 (a nonmetallic container), a heating element inside the water tank and/or surrounding the water tank such as a resistive heating element or fluid passages configured to have a heated fluid flowed therethrough, or another method of heating known to heat water. In addition, the degassed and preheated de-ionized water 414 is may be hydrogenated prior to use. The de-ionized water 414 may be saturated with hydrogen as the presence of hydrogen may reduce the initiation time during deposition. Hydrogenation of the de-ionized water may be accomplished by bubbling a hydrogen gas or forcing hydrogen gas through de-ionized water 414 while contained in water container 410. The degassed and preheated de-ionized water 414 serves as both a diluent and a heat source in forming the plating solutions.

The electroless plating solution is formed by in-line mixing the de-ionized water and the componential concentrates, specifically conditioning buffer concentrate 440, cobalt-containing concentrate 450 and buffered reducing concentrate 460. In one embodiment, the componential concentrates are combined with the de-ionized water and used to deposit a cobalt-containing layer on a pre-cleaned surface of substrate 510.

A metered flow of de-ionized water 414 is first combined and mixed with a metered flow of conditioning buffer concentrate 440 stored in container 436. A metering pump 427 is used to deliver a desired flow rate of conditioning buffer concentrate 440 at about point A, after which in-line mixer 470 is used to promote thorough mixing. A flow of cobalt-containing concentrate 450 is added using metering pump 428 from container 448 and mixed with the flow of heated degassed water and conditioning buffer concentrate 440 with mixing at about point B using in-line mixer 472.

Finally a flow of buffered reducing concentrate 460, stored in vessel 458, is added using metering pump 429 at about point C to and mixed through a final in-line mixing device 474 to provide the complete mixed plating solution. This flow of the mixed electroless plating solution may be dispensed either directly on the wafer to be plated, or for greater flexibility and accuracy, to a temperature controlled buffer vessel 480. The heated buffer vessel 480 may utilize an external heated water jacket to regulate the temperature. The heated buffer vessel 480 maintains the electroless plating solution at a temperature in a range from about 60° C. to about 70° C., or more generally between about 5° C. and 10° C. below the target plating temperature on the wafer surface as controlled by the hot water flowing over the backside.

In another embodiment, an in situ clean process is administered to the surface of substrate 510 prior to the depositing the cobalt-containing layer. In one example, an in situ clean process is provided by combining the conditioning buffer concentrate 440 with de-ionized water 414 to form a cleaning solution. A metering pump 427 is used to deliver a desired flow rate of conditioning buffer concentrate 440 to insulated conduit 418 and combined with a flow of the de-ionized water 414 at about point A, thereby forming a flow of a dilute conditioning buffer solution having a desired ratio, typically between about 7:1 and about 3:1 based on the formulations already specified. The dilute conditioning cleaner may be dispensed directly over the substrate, which is rotated at about 60 rpm or faster while the dispense nozzle is swept across the surface. Typical pre-clean time ranges between about 5 seconds and about 15 seconds, after which the flow of dilute pre-clean is switched to a flow of the complete mixed plating bath from the buffer vessel. As previously specified, the diluted, complete plating bath mixture in the buffer vessel is prepared less than about 10 minutes prior to use and maintained at about 5° C. to about 10° C. less than the desired plating temperature determined by the heated water impinging on the back side of the substrate. Advantages associated with the use of this in-situ clean sequence include a substantial reduction in processing time and rinse and waste volumes associated with acidic pre-clean operations. In contrast to acidic pre-clean steps which may be performed outside the deposition chamber, it is advantageous to perform alkaline conditioning buffer/cleaner based pre-clean steps in the same chamber immediately prior to plating, allowing intermediate rinse to be eliminated. Is particularly critical to perform such pre-cleans in an environment substantially free of oxygen to avoid surface corrosion of copper. Preparation of dilute condition/cleaner using degassed heated water with <1 ppm oxygen and operation in an environment with less than about 150 ppm oxygen is preferred to avoid resistance increases associated with copper corrosion.

The use of smaller volumetric quantities of the plating solution to deposit the desired film has many advantages over a traditional electroless bath, such as more consistently deposited layers per substrate and less hazardous waste. Generally, a fresh volume of a plating solution is exposed to each successive substrate. The concentrations of the individual components in the plating solution are dilute in comparison to more traditional solutions. Traditional bath solutions for electroless deposition processes rely on higher concentrations of each component so that individual substrates within each substrate batch have a relatively consistent exposure to each plating component within the bath. Embodiments of this invention provide processes to expose the substrates to small volumes of a plating solution so that each substrate is exposed to a virgin plating solution that has a repeatable concentration.

Also, embodiments of the invention take advantage of the low concentrations of various components within the plating solution to minimize the amount of waste of unused components. Once a sufficient thickness of the cobalt containing alloy has been deposited, most of the other plating solution constituents will also be consumed so the amount of waste is decreased. The waste stream is less hazardous than traditional solutions due to less metal ions within the solution. In one embodiment, the depleted plating solution is delivered across a heated baffle (e.g., about 75° C. to about 95° C.) to further plate out residue metal atoms from the solution. Once all or most of the metal ions and reductants are removed, the solution may be purified by ion exchange and/or disposed of as non-hazardous waste.

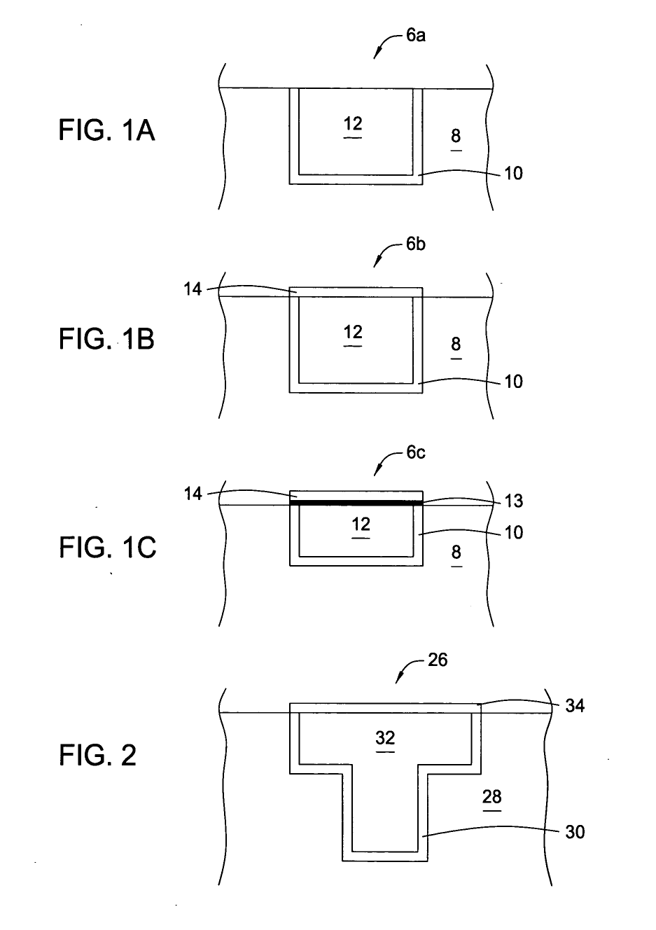

FIG. 1A shows a cross-sectional view of an interconnect 6a containing a conductive material 12 disposed into a dielectric material 8, such as a low-k dielectric material. Conductive material 12 is a metal, such as copper or a copper alloy. The conductive material is generally deposited by a deposition process, such as electroplating, electroless plating, physical vapor deposition (PVD), chemical vapor deposition (CVD), atomic layer deposition (ALD) and/or combinations thereof. As depicted in FIG. 1A, conductive material 12 may have already been polished or leveled, such as by a chemical-mechanical plating (CMP) technique. Low-k material 8 may include features, such as electrodes or interconnects, throughout the layer (not shown). A barrier layer 10 separates low-k material 8 from the conductive material 12. Barrier layer 10 includes materials such as tantalum, tantalum nitride, tantalum silicon nitride, titanium, titanium nitride, tungsten nitride, silicon nitride, and/or combinations thereof and is usually deposited with a PVD, ALD or CVD technique.

Interconnect 6a, as well as other semiconductor features, are formed on a substrate surface. Substrates on which embodiments of the invention may be useful include, but are not limited to semiconductor wafers, such as crystalline silicon (e.g., Si<100> or Si<111>), silicon oxide, silicon germanium, doped or undoped polysilicon, doped or undoped silicon wafers, silicon nitride and patterned or non-patterned wafers. Surfaces may include bare silicon wafers, films, layers and materials with dielectric, conductive or barrier properties and include aluminum oxide and polysilicon. A substrate may include a glass panel that contains copper features. The surfaces may be pretreated by one or more processes including planarization (e.g., CMP), plating (e.g., ECP), etching, reduction, oxidation, hydroxylation, annealing and baking. Substrate surface is used herein to refer to any semiconductor feature present thereon, including the exposed surfaces of the features, such as the wall and/or bottom of vias, trenches, dual damascenes, contacts and the like.

FIG. 1B depicts a cross-sectional view of interconnect 6b including a cobalt-containing alloy layer 14 that is a capping layer deposited on the conductive material 12. The cobalt-containing alloy layer 14 is deposited by exposing the conductive material 12 to a plating solution as described in the various embodiments of the invention. The cobalt-containing alloy layer is deposited with a thickness from about an atomic layer to about 500 Å, preferably from about 10 Å to about 300 Å and more preferably from about 50 Å to about 200 Å. The cobalt-containing alloy layer may be deposited in several steps. For example, the substrate surface is exposed to a first volume of plating solution to deposit a first layer with a first thickness (e.g., 100 Å) and the substrate surface is exposed to a second volume of plating solution to deposit a second layer with a second thickness (e.g., 100 Å) to form an overall cobalt-containing alloy layer.

The cobalt-containing alloy layer may include a variety of compositions containing cobalt, tungsten or molybdenum, phosphorus, boron and combinations thereof. Generally, cobalt-containing alloys have a composition in atomic percent, such as a cobalt concentration in a range from about 85% to about 95%, a tungsten concentration in a range from about 1% to about 6% or a molybdenum concentration in a range from about 1% to about 6%, and a phosphorus concentration in a range from about 1% to about 12%, preferably from about 3% to about 9%. A variable amount of boron may be present in cobalt-containing alloys prepared with the methods of the invention due to the inclusion of a borane reductant. In some embodiments, the substitution of molybdenum for tungsten may have economic advantages during deposition processes of cobalt-containing alloys.

The concentration of phosphorus and/or boron within a cobalt-containing alloy layer can affect how amorphous the deposited capping layer may end up. Generally, the barrier properties (e.g., less diffusion of copper, oxygen or water) increases as the capping layer becomes more amorphous. Alternatively, the effect of phosphorus or boron may result from the “stuffing” of grain boundaries which can tend to inhibit copper diffusion through the capping layer.

Generally, oxygen is unintentionally incorporated into the cobalt-containing alloys. The metal oxides are generally near the surface of the cobalt-containing alloy and have a concentration of less than 0.5 at %. The cobalt-containing alloy near the conductive material 12 surface has an oxygen concentration of less than 0.05%. Substantial amounts of oxygen are not desirable within a cobalt-containing alloy, since barrier properties and conductivity are reduced as oxygen concentration increases. In some embodiments of the invention, oxygen concentration of the cobalt-containing alloy is minimized to a range from about 5×10¹⁸ atoms/cm³ to about 5×10¹⁹ atoms/cm³. The lower oxygen concentration is in part due to the more efficient reduction of the cobalt-containing alloy resulting from the precursors, such as the hypophosphite source and the borane-base co-reductant and the relative high concentration ratio of metal ions to reductant.

In an alternative embodiment depicted by FIG. 1C, prior to the deposition of cobalt-containing alloy 14, an initiation layer 13 may be formed on the exposed conductive material 12 by displacement plating of a catalytic metal such a palladium, platinum, ruthenium, osmium, rhodium or iridium. Typical procedures for cleaning and displacement plating of copper with palladium employ dilute aqueous acid solutions of palladium salts such as palladium chloride, palladium nitrate or palladium sulfate. An example of a suitable acidic activation solution is one prepared by addition of about 1 mL of a 10 wt % Pd(NO₃)₂ in 10% nitric acid to 1 L of deionized water. In another example, an activation solution contains about 120 ppm palladium chloride and sufficient hydrochloric acid to provide a pH in a range from about 1.5 to about 3. Substrates to be activated are exposed to the activation solution for about 30 seconds at ambient temperature.

To avoid contamination of deposition hardware by particles, the initiation and cobalt containing alloy deposition processes are generally performed separately and/or are followed by complexation and rinse steps. Alternatively, a catalytic metal may be deposited by electroless plating without the displacement of any significant amount of copper. In one embodiment, a suitable metal precursor may be added to the cobalt-containing solution, either premixed or mixed in-line, so that initiation and deposition may be performed in a single step.

In other embodiments, the substrate is exposed to a complexing agent solution to clean the substrate surface and remove remaining contaminants from any of the early processes. The complexing agent solution may be exposed to the substrate between a CMP process and the deposition of the initiation layer 13, and/or between deposition of the initiation layer 13 and deposition of the cobalt-containing alloy, and/or between the CMP process and deposition of the cobalt-containing alloy. Complexing agents are useful to chelate and extract metal ions, such as copper (e.g., Cu₂O or CuO) or Pd²⁺ from dielectric surfaces and conductive surfaces. Generally, the substrate surface is exposed to the complexing agent solution for a period from about 5 seconds to about 60 seconds, preferably from about 10 seconds to about 30 seconds. The complexing agent solution is an aqueous solution containing a complexing agent. Complexing agents generally may have functional groups such as amino acids, carboxylic acids, dicarboxylic acids, polycarboxylic acids, and amines, diamines and polyamines. Complexing agents may include citric acid, glycine, amino acids, EDA, derivatives thereof, salts thereof, and combinations thereof. In one example, the complexing agent solution contains citric acid with a concentration in a range from about 50 mM to about 200 mM and adjusted with the addition of TMAH or (CH₃)₄NOH to a pH of about 3.

In other embodiments, the substrate is exposed to a rinse process to further clean the substrate surface and remove remaining contaminants from any of the early processes. A rinse process will general follow each process, such as CMP process, deposition of initiation layer, deposition of cobalt-containing alloy layer and/or exposure to complexing solution. The rinse process includes washing the surface with deionized water. The substrate will be rinsed for a period from about 1 second to about 30 seconds, preferably from about 5 seconds to about 10 seconds.

FIG. 2 shows a cross-sectional view of a dual damascene structure 26 containing a conductive material 32 disposed into low-k material 28 separated by barrier layer 30. Cobalt-containing alloy layer 34 is deposited on the conductive material 32 in the dual damascene structure 26 by utilizing the various embodiments of the invention. The surface of conductive material 32 may be initiated with a noble metal, as discussed above.

In a preferred embodiment, the cobalt-containing alloy is deposited onto a conductive layer on substrate containing contaminants by employing an in-situ clean solution. Therefore, the substrate surface does not have to be cleaned or activated before depositing the cobalt-containing alloy. Prior to cobalt-containing alloy deposition, substrate surfaces generally contain contaminates, such as oxide, copper oxides, BTA, surfactant residues, derivatives thereof and combinations thereof. Contaminants include various residues remaining from previous CMP and post clean process steps. Therefore, a plating solution containing a conditioning buffer solution, a cobalt-containing solution, a buffered reducing solution and water is used directly on the substrate surface.

### EXAMPLES

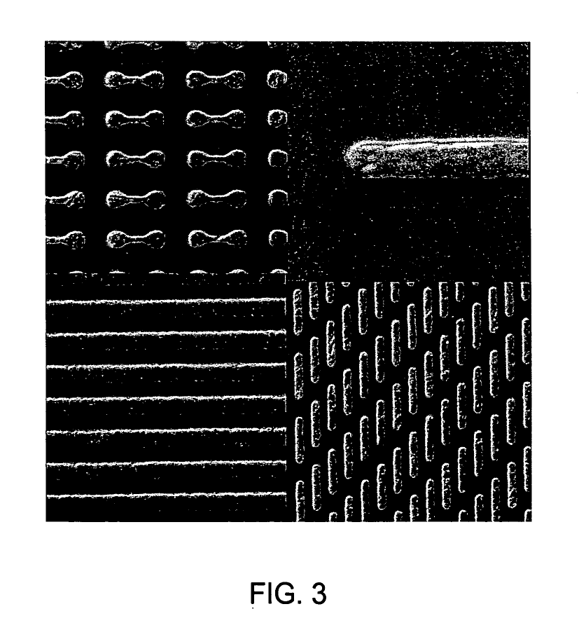

In the following examples, 300 mm silicon AMAT MTC CD90 E-test pattern wafers were used as sample substrates for electroless deposition of cobalt-containing alloys. The substrates contained exposed copper interconnect structures, such as lines, pads and vias, that were electrically isolated within the dielectric film. The substrate surface was polished by a CMP process and subsequently selectively coated with a CoWP alloy film by an electroless plating process, as described in embodiments above. The plating process utilized a face up “puddle plating” process. Continuous and uniform cobalt-containing films were selectively grown on the different copper surfaces as shown by images from a scanning electron microscope (SEM), as shown in FIG. 3.

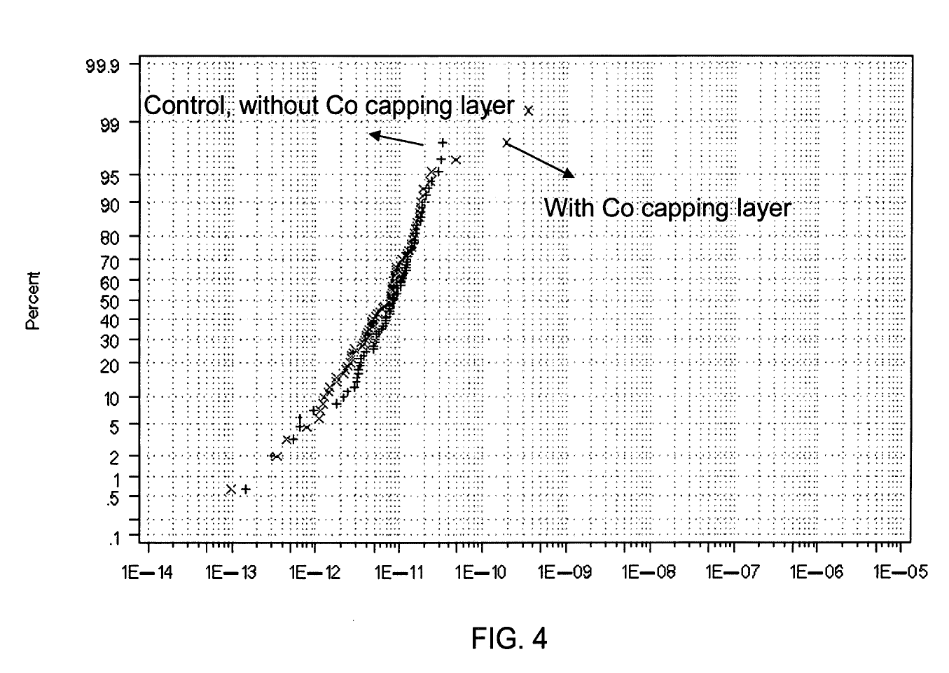

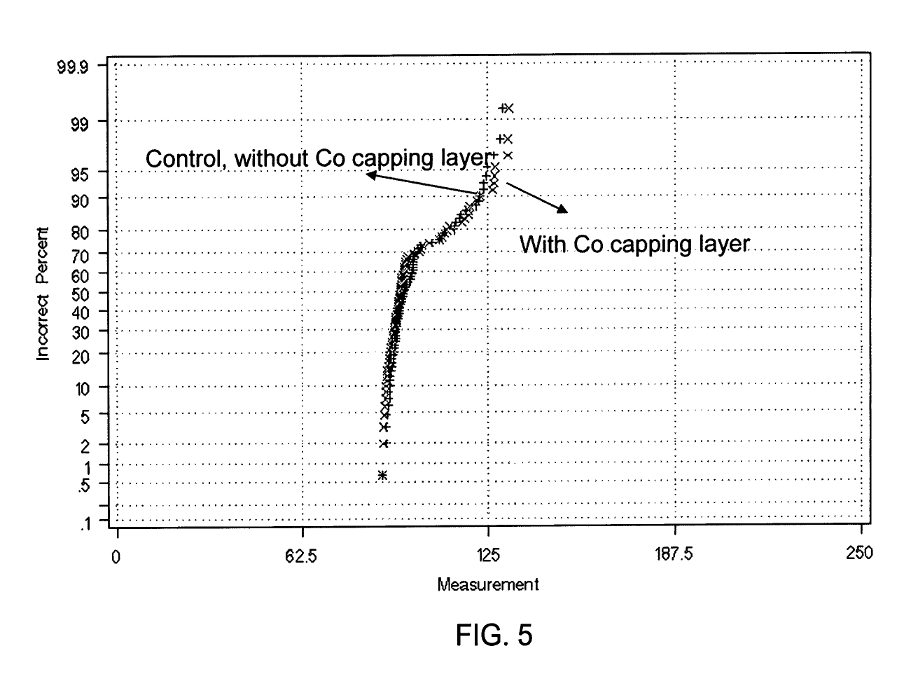

In FIG. 4, the measured electrical performance of interconnect lines with cobalt capping layers shows no significant difference of current leakage compared with the same line structures without cobalt-containing capping layers, as shown in FIG. 5. Also, the line resistance of cobalt-capped line structures had no more than a 2%, if any, increase when compared to the same line structures without cobalt-containing capping layers. The deposition process may be controlled to deposit a cobalt-containing capping layer with a thickness from about 50 ∈ to about 300 Å, with a plating rate of about 60 Å/min. The plating rate may be controlled by adjusting the pH and temperature of the deposition solution, such as increasing the rate with a higher pH and temperature.

In the examples, the substrates were processed by four major steps: 1) surface pre-clean to remove copper oxide and residues on the dielectric surfaces; 2) electroless plating of cobalt-containing layer; 3) post-cleaning to remove residue on the surface, especially on dielectric surfaces; and 4) rinse and dry step. In one example, steps 1-4 were implemented in one chamber with two cell configurations. The chamber was filled with dry nitrogen containing an oxygen concentration of about 150 ppm or less. The pre-clean step was preformed at room temperature (about 20° C.) in the pre-clean cell. The substrate was transferred to a pedestal inside the cell with the exposed copper structures facing up. The dispense arm on top of the substrate had controlled sweep capability and held several chemical inlets, including pre-clean solution and de-ionized water. The substrate was wetted with de-ionized water. Next, the pre-clean solution was dispensed onto the substrate surface while the substrate was rotated at 120 rpm. After about 30 seconds, the substrate was rinsed with de-ionized water. The aqueous pre-clean solution contained citric acid with a pH value from about 1.7 to about 3.0. The more heavily oxidized surfaces typically required more aggressive cleaning at lower pH values.

The substrate is then delivered to a hot diffusion plate which has de-ionized water flowed through the center of the pedestal to contact the backside of the substrate. After the pre-clean step was performed, the substrate was transferred into a plating cell which was maintained under the same nitrogen environment. The temperature controlled hot de-ionized water flowing through the diffuser plate provided heat for the substrate and avoided exposure of chemical contaminates on the backside of the substrate. The substrate temperature was maintained at a temperature between about 70° C. and 85° C., preferably about 80° C. A plating solution which was prepared by the point of use in-line mixing kits, as discussed above, was then delivered to the substrate surface. The plating solution contained any conditioning buffer solution, cobalt containing solution, and a buffered reducing solution which were mixed with de-gassed hot de-ionized water maintained at a temperature between about 80° C. and 95° C., preferably about 85° C. The conditioning buffer solution, cobalt containing solution, buffered reducing and the water were in a volumetric ratio of 2:1:1:6.

The mixed plating solution was kept in a 500 mL vessel which was constantly maintained at a temperature between about 60° C. and about 70° C., preferably about 65° C., for about 10 minutes, preferably about 2 minutes or less, before dispensing on the substrate surface. The hot de-ionized water used in the plating solution was degassed to an oxygen concentration of about 2 ppm or less. The buffered reducing solution, the conditioning buffer solution and the hot de-ionized water were first combined, before adding with cobalt containing solution. This order of mixing solutions was used to help avoid cobalt particle formation within the plating solution. The substrate was transferred to the deposition cell and lowered to have direct contact with the hot water through the diffuser plate while being rotated. The plating solution was dispensed on the substrate surface for about 7 seconds and the substrate was rotated at a rate of about 30 rpm to about and 100 rpm to quickly and uniformly disperse the plating solution across the substrate surface. The rotation rate of the substrate was slowed down to less than about 10 rpm and plated for a period of time from about 30 seconds to about 70 seconds.

For a single dispense process, about 150 mL of plating solution was used to form the cobalt containing layer, while for multiple dispense processes, such as three dispenses, about 250 mL of plating solution was used to form the cobalt containing layer. In order to form a cobalt containing layer with a thickness of about 100 Å or larger, multiple dispenses of the plating solution was found to improve the deposition process by avoiding the effects of the evaporation of water.

De-ionized water rinse was implemented at the end of each plating process and the substrate was lifted from the pedestal near the end of de-ionized rinse step to equilibrate the substrate to about room temperature. The post clean solution was dispensed on top of the substrate surface at room temperature while the substrate was rotated at about 120 rpm. The preferred post clean solution contains methanesulfonic acid (MSA) in de-ionized water a concentration range from about 10 mM to about 50 mM, preferably about 20 mM. The substrate was rinsed with de-ionized water and dried.

While the foregoing is directed to embodiments of the present invention, other and further embodiments of the invention may be devised without departing from the basic scope thereof, and the scope thereof is determined by the claims that follow.

1. A method for forming an electroless deposition solution, comprising:
forming a conditioning buffer solution with a first pH value and comprising a first complexing agent;
forming a cobalt-containing solution with a second pH value and comprising a cobalt source, a tungsten source and a second complexing agent;
forming a buffered reducing solution with a third pH value and comprising a hypophosphite source and a borane reductant;
combining the conditioning buffer solution, the cobalt-containing solution and the buffered reducing solution to form an electroless deposition solution comprising:
a cobalt concentration range from about 1 mM to about 30 mM;
a tungsten concentration range from about 0.1 mM to about 5 mM;
a hypbphosphite concentration range from about 5 mM to about 50 mM;
a borane concentration range from about 5 mM to about 50 mM; and
a total pH value in a range from about 8 to about 10.

2. The method of claim 1, wherein the buffered reducing solution further comprises a third complexing agent.

3. The method of claim 2, wherein the first, second and third complexing agents are independently selected from the group consisting of citric acid, citrates, glycine, alkanolamines derivatives thereof, salts thereof and combinations thereof.

4. The method of claim 3, wherein the first, second and third complexing agents are citrates.

5. The method of claim 4, wherein the electroless deposition solution has a citrate concentration in a range from about 50 mM to about 300 mM.

6. The method of claim 3, wherein the first, second and third pH values are substantially the same and are in a range from about 8 to about 10.

7. The method of claim 6, wherein water is combined with the conditioning buffer solution, the cobalt-containing solution and the buffered reducing solution to form the electroless deposition solution.

8. The method of claim 7, wherein the water is at a water temperature greater than that of the buffered reducing solution.

9. The method of claim 8, wherein the water temperature is from about 70° C. to about 95° C.

10. The method of claim 9, wherein the electroless deposition solution has a temperature from about 50° C. to about 80° C.

11. The method claim 7, wherein the water has an oxygen concentration of about 1 ppm or less.

12. The method claim 7, wherein the electroless deposition solution has an oxygen concentration of about 3 ppm or less.

13. A kit for forming an electroless deposition solution, comprising:
a conditioning buffer solution having a first pH value and comprising a first complexing agent;
a cobalt-containing solution having a second pH value and comprising a cobalt source, a secondary metal source and a second complexing agent;
a buffered reducing solution having a third pH value and comprising a hypophosphite source and a borane reductant;
instructions to combine at least the conditioning buffer solution, the cobalt-containing solution and the buffered reducing solution to form an electroless deposition solution.

14. The kit of claim 13, wherein the secondary metal source is selected from a group consisting of a tungsten source or a molybdenum source.

15. The kit of claim 14, wherein the secondary metal source is the tungsten source and has a concentration in the cobalt-containing solution in a range from about 1 mM to about 30 mM.

16. The kit of claim 14, wherein the secondary metal source is the molybdenum source and has a concentration in the cobalt-containing solution in a range from about 100 ppm to about 300 ppm.

17. The kit of claim 15, wherein the cobalt source has a concentration in the cobalt-containing solution in a range from about 50 mM to about 150 mM.

18. The kit of claim 17, wherein the hypophosphite source has a concentration in the buffered reducing solution in a range from about 200 mM to about 300 mM.

19. The kit of claim 18, wherein the borane reductant has a concentration in the buffered reducing solution from about 100 mM to about 300 mM.

20. The kit of claim 19, wherein the buffered reducing solution further comprises a third complexing agent.

21. The kit of claim 20, wherein the first, second and third complexing agents are independently selected from the group consisting of citric acid, citrates, glycine, alkanolamines, derivatives thereof, salts thereof and combinations thereof.

22. The kit of claim 21, wherein the first, second and third complexing agents are citrates.

23. The kit of claim 22, wherein the conditioning buffer solution, the cobalt-containing solution and the buffered reducing solution each have a citrate concentration in a range from about 200 mM to about 500 mM.

24. The kit of claim 23, wherein the first, second and third pH values are substantially the same and are in a range from about 8 to about 10.

25. A kit for forming a citrate-based deposition solution, comprising:
a conditioning buffer solution having a first pH value and comprising citrate and an alkanolamine;
a cobalt-containing solution having a second pH value and comprising a cobalt source, a secondary metal source and citrate;
a buffered reducing solution having a third pH value and comprising a hypophosphite source, a borane reductant and citrate;
instructions to combine at least the conditioning buffer solution, the cobalt-containing solution and the buffered reducing solution to form a citrate-based deposition solution.

26. The kit of claim 25, wherein a citrate concentration of the citrate-based deposition solution is in a range from about 50 mM to about 300 mM.

27. The kit of claim 26, wherein the cobalt source and the secondary metal source have a combined metal concentration in a range from about 8 mM to about 15 mM.

28. The kit of claim 27, wherein the citrate concentration and the combined metal concentration are at a molar ratio of about 8:1 or larger.

29. The kit of claim 28, wherein the molar ratio is about 10:1 or larger.

30. The kit of claim 29, wherein the molar ratio is about 12:1 or larger.

31. A method to deposit a cobalt-containing layer on a conductive layer disposed on a substrate surface by an electroless deposition process, comprising:
combining a first volume of a conditioning buffer solution, a second volume of a cobalt-containing solution and a third volume of a buffered reducing solution to form a plating solution; and
forming a cobalt-containing layer on the conductive layer by exposing the substrate surface to the plating solution.

32. The method of claim 31, wherein the plating solution further comprises a fourth volume of water.

33. The method of claim 32, wherein the fourth volume of water has a water temperature greater than a plating solution temperature.

34. The method of claim 33, wherein the water temperature is in a range from about 70° C. to about 95° C.

35. The method of claim 34, wherein the plating solution temperature is in a range from about 50° C. to about 80° C.

36. The method of claim 35, wherein the first volume, the second volume, the third volume and the fourth volume are combined with approximate volumetric ratios of about 1:1:1:7.

37. A composition of a plating solution, comprising:
a cobalt source in a concentration range from about 5 mM to about 15 mM;
a tungsten source in a concentration range from about 1 mM to about 3 mM;
a hypophosphite source in a concentration range from about 15 mM to about 35 mM;
a borane reductant in a concentration range from about 10 mM to about 30 mM;
a citrate in a concentration range from about 90 mM to about 200 mM;
an alkanolamine in a concentration range from about 50 mM to about 150 mM;
boric acid in a concentration range from about 5 mM to about 20 mM;
a surfactant in a concentration range of about 100 ppm or less; and
a pH adjusting agent at a concentration to maintain a pH from about 8 to about 10.

38. The composition of claim 37, wherein the plating solution has an oxygen concentration of 3 ppm or less.

39. The composition of claim 38, wherein the alkanolamine is selected from the group consisting of DEA, TEA, derivatives thereof and combinations thereof.

40. The composition of claim 39, wherein the cobalt source is selected from the group consisting of CoSO₄, CoCl₂, cobalt acetate, water soluble Co²⁺ sources, derivatives thereof, hydrates thereof and combinations thereof.

41. The composition of claim 40, wherein the tungsten source is selected from the group consisting of ammonium tungsten oxide, tungstic acid, water soluble WO₄²⁻ sources, derivatives thereof and combinations thereof.

42. The composition of claim 41, wherein the borane reductant is selected form the group consisting of DMAB, TMAB, ^{t}BuNH₂.BH₃, THF.BH₃, C₅H₅N.BH₃, NH₃.BH₃, borane, diborane, derivatives thereof, complexes thereof and combinations thereof.

43. The composition of claim 42, wherein the surfactant comprises sodium dodecyl sulfate, salts thereof or derivatives thereof.

44. A composition of a plating solution, comprising:
a cobalt source in a concentration range from about 5 mM to about 15 mM;
a secondary metal source in a concentration range of about 5 mM or less;
a hypophosphite source in a concentration range from about 15 mM to about 35 mM;
a borane reductant in a concentration range from about 10 mM to about 30 mM;
a citrate in a concentration range from about 90 mM to about 200 mM;
an alkanolamine in a concentration range from about 50 mM to about 200 mM;
boric acid in a concentration range from about 5 mM to about 20 mM;
a surfactant in a concentration range of about 100 ppm or less; and
a pH adjusting agent at a concentration to maintain a pH from about 8 to about 10.

45. The composition of claim 44, wherein the secondary metal source is selected from a group consisting of a tungsten source or a molybdenum source.

46. The composition of claim 45, wherein the secondary metal source is the tungsten source and has a concentration from about 1 mM to about 3 mM.

47. The composition of claim 45, wherein the secondary metal source is the molybdenum source and has a concentration from about 50 ppm to about 500 ppm.

48. A method to deposit a cobalt-containing layer by an electroless deposition process, comprising:
exposing a conductive layer on a substrate to an activation solution to form an activated conductive layer;
combining heated water, a conditioning buffer solution, a cobalt-containing solution and a buffered reducing solution to form a plating solution; and
exposing the activated conductive layer to the plating solution to deposit the cobalt-containing layer.

49. The method of claim 48, wherein the activation solution comprises a palladium source.

50. A method for forming an electroless deposition solution, comprising:
maintaining a conditioning buffer solution at a first temperature;
maintaining a metal-containing solution at a second temperature;
maintaining a reducing solution at a third temperature;
maintaining water at a fourth temperature; and
combining the conditioning buffer solution, the metal-containing solution, the reducing solution and the water to form an electroless deposition solution at a fifth temperature.

51. The method of claim 50, wherein the first, second and third temperatures are substantially the same.

52. The method of claim 51, wherein the first, second and third temperatures are about 30° C. or less.

53. The method of claim 50, wherein the fourth temperature is higher than the fifth temperature.

54. The method of claim 53, wherein the fourth temperature is in a range from about 75° C. to about 95° C.

55. The method of claim 54, wherein the fifth temperature is in a range from about 55° C. to about 75° C.

56. A method for forming an electroless deposition solution, comprising:
removing oxygen from water to have an oxygen concentration of about 1 ppm or less; and
combining a conditioning buffer solution, a cobalt-containing solution, a buffered reducing solution and the water to form an electroless deposition solution having a second oxygen concentration of about 3 ppm or less.

57. A method for forming an electroless deposition solution, comprising:
forming a conditioning buffer solution comprising at least two complexing agents;
forming a cobalt-containing solution;
forming a buffered reducing solution; and
combining heated water, the conditioning buffer solution, the cobalt-containing solution and the buffered reducing solution to form an electroless deposition solution.

58. The method of claim 57, wherein the at least two complexing agents are selected from a group consisting of a carboxylic acid, an alkanolamine, an amino acid, salts thereof, derivatives thereof and combinations thereof.

59. The method of claim 58, wherein the at least two complexing agents are selected from the group consisting of a citrate, DEA, TEA, glycine, derivatives thereof and combinations thereof.

60. A process for forming a citrate-based deposition solution, comprising:
combining water, a conditioning buffer solution, a metal-containing solution and a buffered reducing solution to form a citrate-based deposition solution, wherein the conditioning buffer solution comprises citrate and an alkanolamine, the metal-containing solution comprises a metal source and citrate, and the buffered reducing solution comprises a hypophosphite source and citrate.

61. The process of claim 60, wherein a citrate concentration of the citrate-based deposition solution is in a range from about 50 mM to about 300 mM.

62. The process of claim 61, wherein the metal source has a metal concentration in the citrate-based deposition solution in a range from about 8 mM to about 15 mM.

63. The process of claim 62, wherein the citrate concentration and the metal concentration are at a molar ratio of about 8:1 or larger.

64. The process of claim 63, wherein the molar ratio is about 10:1 or larger.

65. The process of claim 64, wherein the molar ratio is about 12:1 or larger.

66. A method to deposit a cobalt-containing layer by an electroless deposition process on a substrate surface containing a conductive layer, comprising:
exposing the substrate surface with a conditioning buffer solution to form a cleaned conductive layer;
combining the conditioning buffer solution, a cobalt-containing solution and a reducing solution to form a plating solution; and
exposing the cleaned conductive layer to the plating solution to deposit the cobalt-containing layer thereon.

67. The method of claim 66, wherein the conditioning buffer solution comprises at least two complexing agents.

68. The method of claim 67, wherein the at least two complexing agents are selected from a group consisting of a carboxylic acid, an alkanolamine, an amino acid, salts thereof, derivatives thereof and combinations thereof.

69. The method of claim 68, wherein the at least two complexing agents are selected from the group consisting of a citrate, DEA, TEA, glycine, derivatives thereof and combinations thereof.

70. A method to deposit a cobalt-containing layer by an electroless deposition process on a substrate surface containing a conductive layer, comprising:
exposing the substrate surface with a cobalt-containing solution to form a cleaned conductive layer;
combining heated water, a conditioning buffer solution, the cobalt-containing solution and a buffered reducing solution to form a plating solution; and
exposing the cleaned conductive layer to the plating solution to deposit the cobalt-containing layer thereon.

71. The method of claim 70, wherein the buffered reducing solution has a hypophosphite source concentration in a range from about 200 mM to about 300 mM.

72. The method of claim 71, wherein buffered reducing solution has a borane reductant concentration in a range from about 100 mM to about 300 mM.

73. An apparatus for forming an electroless deposition solution, comprising:
a first vessel containing a conditioning buffer solution comprising a citrate;
a second vessel containing a metal-containing solution comprising a metal source and citrate;
a third vessel containing a buffered reducing solution comprising a hypophosphite source and citrate;
a water source of heated, deionized degassed water; and
a fourth vessel in fluid communication with the first, second and third vessels and the water source, wherein the fourth vessel contains the electroless deposition solution.

74. The apparatus of claim 73, further comprising a nozzle in fluid communication with the fourth vessel, wherein the nozzle is positioned above a substrate surface.

75. The apparatus of claim 74, further comprising a heated baffle used to reduce metal concentration of a depleted electroless deposition solution.

76. The apparatus of claim 75, wherein at least one in-line mixer is positioned between the first vessel and the fourth vessel.

77. The apparatus of claim 76, wherein at least three in-line mixers are positioned between the first vessel and the fourth vessel.

78. A method for forming an electroless deposition solution, comprising:
maintaining a metal-containing concentrate at a first temperature;
maintaining a reducing concentrate at a second temperature;
maintaining water at a fourth temperature; and
combining the metal-containing concentrate, the reducing concentrate and the water to form an electroless deposition solution at a fourth temperature.

79. The method of claim 78, wherein the first and second temperatures are substantially the same.

80. The method of claim 79, wherein the first and second temperatures are about 30° C. or less.

81. The method of claim 78, wherein the third temperature is higher than the fourth temperature.

82. The method of claim 81, wherein the third temperature is in a range from about 75° C. to about 95° C.

83. The method of claim 82, wherein the fourth temperature is in a range from about 55° C. to about 75° C.

84. A method for forming an electroless deposition solution, comprising:
forming a conditioning buffer solution comprising a first complexing agent;
forming a cobalt-containing solution comprising a cobalt source, a tungsten source and a second complexing agent;
forming a buffered reducing solution comprising a hypophosphite source and a borane reductant;
combining heated water, the conditioning buffer solution, the cobalt-containing solution and the buffered reducing solution with an in-line mixing process to form the electroless deposition solution; and
dispersing the electroless deposition solution to a substrate surface within a time of about 60 minutes or less after forming the electroless deposition solution.

85. The method of claim 84, wherein the time is about 10 minutes or less.

86. The method of claim 85, wherein the time is about 2 minutes or less.

87. The method of claim 84, wherein the substrate is exposed to a pre-clean process prior to being exposed to the electroless deposition solution.

88. The method of claim 87, wherein the pre-clean process is conducted in a first cell and the electroless deposition solution is dispersed into a second cell.

89. The method of claim 88, wherein the pre-clean process comprises citrate.
